(19) United States
(12) Patent Application Publication
(10) Pub. No.: US 2015/0014706 A1
(43) Pub. Date: Jan. 15, 2015

(54) Vertical Hetero Wide Bandgap Transistor

(71) Applicant: Laurence P. Sadwick, Salt Lake City, UT (US)

(72) Inventor: Laurence P. Sadwick, Salt Lake City, UT (US)

(21) Appl. No.: 14/332,345

(22) Filed: Jul. 15, 2014

Related U.S. Application Data
(60) Provisional application No. 61/846,074, filed on Jul. 15, 2013.

(51) Int. Cl. H01L 29/78; H01L 29/16; H01L 29/20; H01L 29/66

(52) U.S. Cl. CPC H01L 29/7827; H01L 29/66666; H01L 29/1608; H01L 29/2003; H01L 29/66431
USPC 257/77; 438/268; 257/76

(57) ABSTRACT

A vertical hetero transistor provides a wide bandgap, increases the breakdown voltage or reduces the on resistance of the switching transistor or both.

### CROSS REFERENCE TO RELATED APPLICATIONS

The present application claims priority to (is a non-provisional of) U.S. Pat. App. No. 61/846,074, entitled “Vertical Enhancement Hetero Wide Bandgap Transistor”, and filed Jul. 15, 2013 by Laurence P. Sadwick, the entirety of which is incorporated herein by reference for all purposes.

### BACKGROUND

Electrical switches are used for many applications. An important use and application for electrical switches is in power electronics where electrical switches are used in numerous applications including high voltage electrical switches for, for example, for AC to AC, AC to DC, DC to DC, and DC to AC power supplies, power inverters, power converters, electrical vehicle (EV) and a host of other applications. Although there are numerous types of electrical switches including bipolar junction transistors (BJTs) and hetero junction bipolar transistors (HBTs), field effect transistors of a large number of types and varieties including metal oxide semiconductor field effect transistors (MOSFETs), junction field effect transistors (JFETs), insulated gate bipolar transistor (IGBTs), high electron mobility transistors (HEMT), modulation doped field effect transistors (MODFETs), etc., there is still much room for improvement including in terms of both performance and cost. Both lateral (horizontal) and vertical electrical switches are commonplace with each type having its respective advantages and disadvantages. For a number of reasons as the switching voltage increases, usually vertical switching transistors are preferred. A class of vertical transistors that has gained significant popularity is a vertical MOSFET typically made of and based on the semiconductor silicon (Si) materials system including both native and deposited silicon dioxide (SiO2). There are a number of types of vertical FETs including so-called planar vertical FETs/MOSFETs, U vertical FETs/MOSFETs, V vertical FETs/MOSFETs, etc. The maturity of Si processing, manufacturing, and infrastructure is, among other things, impressive and extensive. In terms of cost, it is hard to beat or compete with the cost of Si-based high voltage power devices; however the performance of these devices still has room for improvement.

### SUMMARY

Various embodiments of the present invention provide a transistor structure that permits higher performance from a standard vertical field effect transistor (FET) structure to be realized. The present invention combines the superior blocking performance of a GaN layer with the extremely advanced and mature Si manufacturing and infrastructure. The present invention can be realized and implemented in a number of ways and forms with some exemplary examples provided here within. The present invention replaces the low electric field breakdown of, for example, unintentionally/un-doped or low doped n-type silicon epitaxial material with an electric field breakdown of unintentionally/un-doped or low doped n-type GaN or related epitaxial material as the blocking layer.

The embodiments shown and discussed are intended to be examples of the present invention and in no way or form should these examples be viewed as being limiting of and for the present invention.

This summary provides only a general outline of some embodiments of the invention. The phrases “in one embodiment,” “according to one embodiment,” “in various embodiments”, “in one or more embodiments”, “in particular embodiments” and the like generally mean the particular feature, structure, or characteristic following the phrase is included in at least one embodiment of the present invention, and may be included in more than one embodiment of the present invention. Importantly, such phrases do not necessarily refer to the same embodiment. This summary provides only a general outline of some embodiments of the invention. Additional embodiments are disclosed in the following detailed description, the appended claims and the accompanying drawings.

### BRIEF DESCRIPTION OF THE FIGURES

A further understanding of the various embodiments of the present invention may be realized by reference to the Figures which are described in remaining portions of the specification. In the Figures, like reference numerals may be used throughout several drawings to refer to similar components.

FIG. 1 depicts an n-type GaN epilayer grown on a silicon wafer/substrate that may contain other layers and materials including silicon dioxide (SiO₂), buried oxide(s), other insulators (for example, silicon nitride), other conducting layers, other silicon layers that may be doped or undoped, etc. in accordance with some embodiments of the invention. In some embodiments of the present invention, the substrate or back or bottom support can be Si, SiC, GaN or some other substrate material.

FIG. 2 depicts a thicker n-type GaN epilayer than FIG. 1 grown on a silicon wafer/substrate that may contain other layers and materials including silicon dioxide, buried oxide(s), other insulators, other conducting layers, other silicon layers that may be doped or undoped, etc. in accordance with some embodiments of the invention. In some embodiments of the present invention, the substrate or back or bottom support can be Si, SiC, GaN or some other substrate material.

FIG. 3 depicts a thick n-type GaN epilayer grown on a silicon wafer/substrate that may contain other layers and materials including silicon dioxide, buried oxide(s), other insulators, other conducting layers, other silicon layers that may be doped or undoped, etc. and a stress relieving/management layer in accordance with some embodiments of the invention. In some embodiments of the present invention, the substrate or back or bottom support can be Si, SiC, GaN or some other substrate material.

FIG. 4 depicts a thick n-type GaN epilayer grown on a silicon wafer/substrate that may contain other layers and materials including silicon dioxide, buried oxide(s), other insulators, other conducting layers, other silicon layers that may be doped or undoped, etc. and a stress relieving/management layer that may also be a back contact which may also be used as a drain contact in accordance with some embodiments of the invention. In some embodiments of the present invention, the substrate or back or bottom support can be Si, SiC, GaN or some other substrate material.

FIG. 5 depicts a thick n-type GaN epilayer grown on a silicon wafer/substrate that may contain other layers and materials including silicon dioxide, buried oxide(s), other insulators, other conducting layers, other silicon layers that may be doped or undoped, etc. and a stress relieving/management layer with the silicon above the silicon dioxide removed in accordance with some embodiments of the invention. In some embodiments of the present invention, the substrate or back or bottom support can be Si, SiC, GaN or some other substrate material.

FIG. 6 depicts a thick n-type GaN epilayer grown on a silicon wafer/substrate that may contain other layers and materials including silicon dioxide, buried oxide(s), other insulators, other conducting layers, other silicon layers that may be doped or undoped, etc. and a stress relieving/management layer with the silicon above the silicon dioxide removed and additional layers grown, deposited, patterned, etched, diffused, ion implanted, etc. to produce gate insulator/gate oxide, gate, field oxide, source, etc. in accordance with some embodiments of the invention. In some embodiments of the present invention, the substrate or back or bottom support can be Si, SiC, GaN or some other substrate material.

FIG. 7 depicts a thick n-type GaN epilayer grown on a silicon wafer/substrate that may contain other layers and materials including silicon dioxide, buried oxide(s), other insulators, other conducting layers, other silicon layers that may be doped or undoped, etc. and a stress relieving/management layer with the silicon above the silicon dioxide removed and additional layers grown, deposited, patterned, etched, diffused, ion implanted, etc. to produce gate insulator/gate oxide, gate, field oxide, source, bottom conductive layer, drain contact drain etc. that results in a vertical FET in accordance with some embodiments of the invention. In some embodiments of the present invention, the substrate or back or bottom support can be Si, SiC, GaN or some other substrate material.

FIG. 8A depicts a vertical transistor with a thick Si drift region/blocking layer that may contain other layers and materials including silicon dioxide, buried oxide(s), other insulators, other conducting layers, other silicon layers that may be doped or undoped, etc. and a stress relieving/management layer with the silicon above the silicon dioxide removed and additional layers grown, deposited, patterned, etched, diffused, ion implanted, etc. to produce gate insulator/gate oxide, gate, field oxide, source, bottom conductive layer, drain, drain contact, etc. that results in a vertical FET in accordance with some embodiments of the invention. In some embodiments of the present invention, the substrate or back or bottom support can be Si, SiC, GaN or some other substrate material.

FIG. 8B depicts a perspective view of the transistor of FIG. 8A.

FIG. 9A depicts a vertical transistor with a GaN drift region/blocking layer that may contain other layers and materials including silicon dioxide, buried oxide(s), other insulators, other conducting layers, other silicon layers that may be doped or undoped, etc. and a stress relieving/management layer with the silicon above the silicon dioxide removed and additional layers grown, deposited, patterned, etched, diffused, ion implanted, etc. to produce gate insulator/gate oxide, gate, field oxide, source, bottom conductive layer, drain, drain contact, etc. that results in a vertical FET in accordance with some embodiments of the invention. In some embodiments of the present invention, the substrate or back or bottom support can be Si, SiC, GaN or some other substrate material.

FIG. 9B depicts a perspective view of the transistor of FIG. 9A.

FIG. 10 is a flow diagram of an example method for fabricating a vertical enhancement hetero wide bandgap transistor in accordance with some embodiments of the invention.

### DETAILED DESCRIPTION OF THE INVENTION

A device structure and architecture that provides an enhanced performance switching transistor is disclosed that, for example, increases the breakdown voltage or reduces the on resistance of the switching transistor or both. In some embodiments, the enhanced performance switching transistor comprises a vertical transistor, a non-planar device in which one or more of the elements, such as, but not limited to, the drain, source and/or gate, are vertically stacked. In some embodiments, the enhanced performance switching transistor comprises an enhancement-mode device, in which a positive gate-to-source voltage creates the conductive channel within the transistor. In some other embodiments, the enhanced performance switching transistor comprises a depletion-mode device. In some embodiments, the enhanced performance switching transistor comprises a hetero-device, using differing semiconductor materials for various regions of the transistor.

The transistor may be any suitable type of transistor or other device, such as a MOSFET or field effect transistor of any type and many types of materials including but not limited to metal oxide semiconductor FET (MOSFET), junction FET (JFET), high electron mobility transistor (HEMT), etc., or an insulated gate bipolar transistor (IGBT) or other types of transistor structures including bipolar junction transistors (BJTs), heterojunction bipolar transistors (HBTs), Darlington transistors, etc. and can be made of any suitable material including but not limited to silicon, gallium arsenide, gallium nitride, silicon carbide, etc which has a suitably high voltage rating. A blocking layer with a high electric field breakdown is provided to achieve a high breakdown voltage. The blocking layer in the device may be adapted in any suitable manner, including material selection, thickness, etc., in order to achieve the desired breakdown voltage. Such materials include, among others, GaN and SiC based materials. Although the Figures illustrate GaN drift layers, again other materials such as SiC may also be used. Materials development in other semiconductor materials systems including wide band gap (WBG) materials such as gallium nitride (GaN) and silicon carbide (SiC) and materials based on these WBG materials improve both lateral and vertical device performance including in vertical FETs that contain GaN and/or SiC as part of their structures and architectures including as active layers, blocking layers, substrates, etc. Growing GaN on non-native substrates (heteroepitaxy) can be realized with typically, for example, GaN grown on, for example, GaN (homoepitaxy), SiC and Si substrates with certain types of crystallographic orientations and relationships being employed.

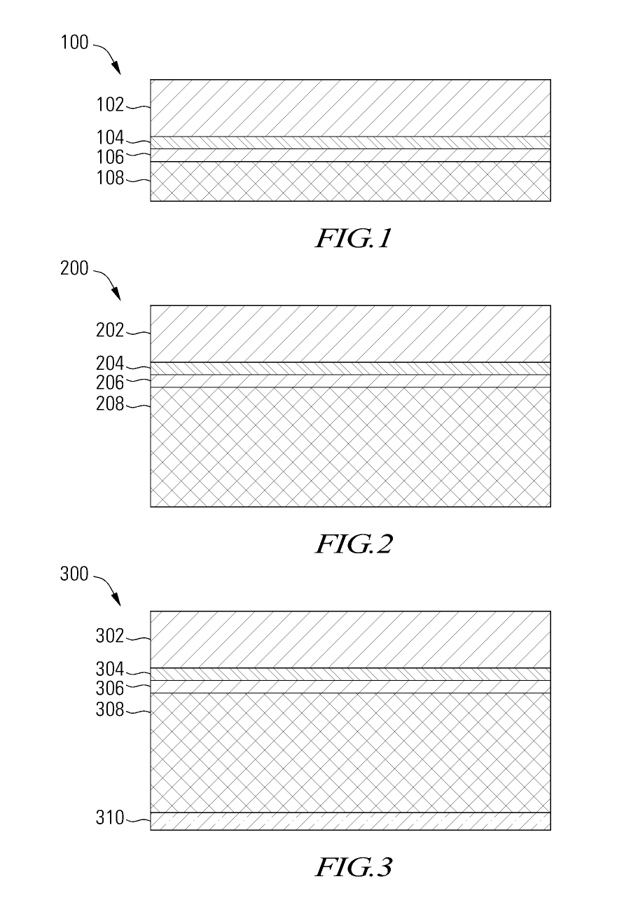

FIG. 1 illustrates an embodiment 100 of the present invention in which an epilayer 108 of GaN is grown or otherwise placed on a silicon substrate 106 that may, for example, contain other elements and materials layers. Such a substrate 106 may, for example, be a silicon on insulator (SOI) type of substrate where, for example, the SOI is made or created by process steps that may include, for example, ion implantation, diffusion, oxidation, bonding, etching, thinning, material removal and or addition, etc. including multiple such steps—for example, multiple diffusion and/or ion implantation steps, etc. For example, the SOI may include multiple layers such as, but not limited to, a Si layer 102, a SiO2 layer 104, and a Si layer 106 on GaN epilayer 108. Other embodiments may use non-SOI wafers including but not limited to Si wafers including pre-processed or post-processed Si wafers or combinations of these, etc.

FIG. 2 depicts and illustrates a similar embodiment 200 as that shown in FIG. 1 except that the GaN layer 208 is thicker from, for example, less than 1 um (micrometer) to greater than 100 um thick with a typical layer being between 5 to 10 um or, for example, 20 um depending on the particulars of the intended application and usage of the present invention including the GaN blocking layer 208. Again, other layers may be applied as desired, such as, but not limited to, Si layer 202, SiO2 layer 204, and Si layer 206 on GaN blocking layer or epilayer 208.

FIG. 3 depicts and illustrates an embodiment 300 including a thick n-type GaN epilayer 308 grown on a silicon wafer/substrate that may contain other layers (e.g., Si layer 302, SiO2 layer 304, and Si layer 306) and materials including silicon dioxide, buried oxide(s), other insulators, other conducting layers, other silicon layers that may be doped or undoped, etc. and also has a stress relieving/management layer 310 to reduce the stress and potential for cracking to a level resulting in a crack free GaN epilayer on Si in accordance with some embodiments of the invention.

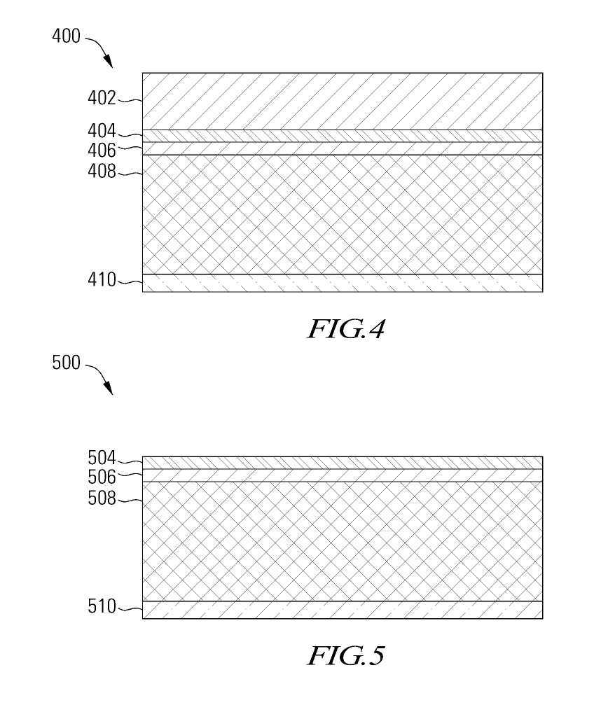

FIG. 4 depicts an embodiment 400 with a thick n-type GaN epilayer 408 grown on a silicon wafer/substrate that may contain other layers and materials including silicon dioxide (e.g., 404), buried oxide(s), other insulators, other conducting layers, other silicon layers (e.g., 402, 406) that may be doped or undoped, etc. and a stress relieving/management layer 410 to reduce the stress and potential for cracking to a level resulting in a crack free GaN epilayer 408 on Si that may also be and serve as a back contact which may also be used as a drain contact in accordance with some embodiments of the invention.

FIG. 5 depicts and illustrates an example embodiment 500 of the present invention in which a thick n-type GaN epilayer 508 grown on a silicon wafer/substrate that may contain other layers and materials including silicon dioxide (e.g., 504), buried oxide(s), other insulators, other conducting layers, other silicon layers (e.g., 506) that may be doped or undoped, etc. and a stress relieving/management layer 510 with the silicon (see, e.g., layer 402 of FIG. 4) above the silicon dioxide layer 504 removed in accordance with some embodiments of the invention.

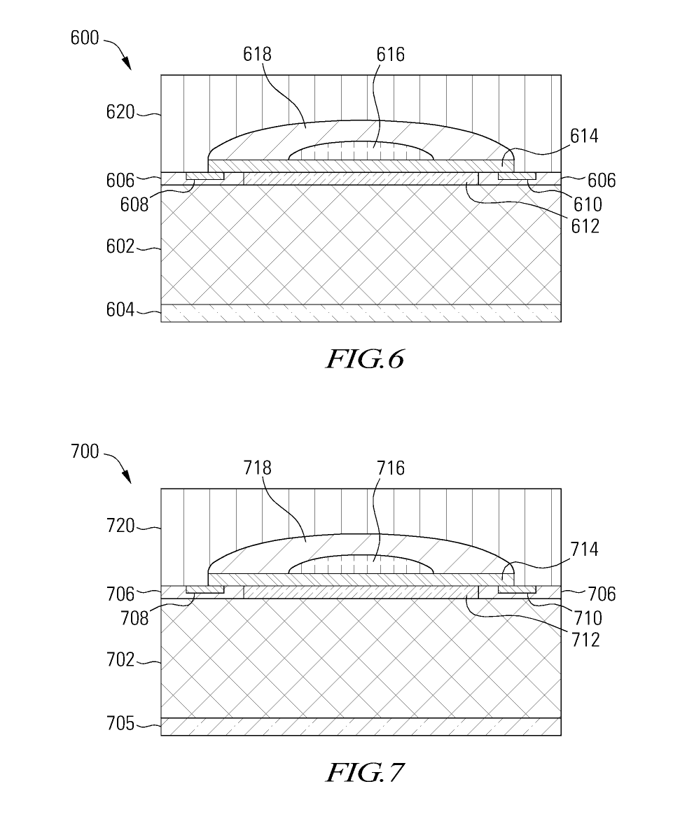

FIG. 6 depicts an embodiment of a transistor 600 with a thick n-type GaN epilayer 602 grown on a silicon wafer/substrate that may contain other layers and materials including silicon dioxide, buried oxide(s), other insulators, other conducting layers, other silicon layers that may be doped or undoped, etc. and a stress relieving/management layer 604 with the silicon above the silicon dioxide removed and additional layers grown, deposited, patterned, etched, diffused, ion implanted, etc. to produce gate insulator/gate oxide, gate, field oxide, source, etc. in accordance with some embodiments of the invention. A standard Si vertical FET process may be used or the process may be modified to the extent needed or desired to achieve the desired performance. For example, the transistor 600 includes a silicon layer on the GaN epilayer 602 and stress relieving/management layer 604, where the silicon layer can be doped as desired, for example forming a P⁻ body 606 with an N⁻ epi region 612 and N⁺ regions 608, 610 underneath a gate oxide 614 in a SiO2 layer. A gate 616 and field oxide 618 are formed over the gate oxide 614 and underneath a source 620. Again, the transistor 600 is not limited to the example shown in FIG. 6 and may be any suitable type of transistor or other device, such as a MOSFET or field effect transistor of any type and many types of materials including but not limited to metal oxide semiconductor FET (MOSFET), junction FET (JFET), high electron mobility transistor (HEMT), etc., or an insulated gate bipolar transistor (IGBT) or other types of transistor structures including bipolar junction transistors (BJTs), heterojunction bipolar transistors (HBTs), Darlington transistors, etc. and can be made of any suitable material including but not limited to silicon, gallium arsenide, gallium nitride, silicon carbide, etc which has a suitably high voltage rating.

Referring to FIG. 7, an embodiment of a transistor 700 with a thick n-type GaN epilayer 702 grown on a silicon wafer/substrate is depicted that may contain other layers and materials including silicon dioxide, buried oxide(s), other insulators, other conducting layers, other silicon layers that may be doped or undoped, etc. and a stress relieving/management layer 705 with the silicon above the silicon dioxide removed and additional layers grown, deposited, patterned, etched, diffused, ion implanted, etc. to produce gate insulator/gate oxide 714, gate 716, field oxide 718, source 720, etc. in accordance with some embodiments of the invention. A standard Si vertical FET process may be used or the process may be modified to the extent needed or desired to achieve the desired performance. A stress relieving/management layer 705 or multiple such layers of a similar nature or purpose within and part of the present invention may be used to control and manage the stress of the present invention. One of the stress management layers 705 may also serve as the back drain contact or a separate drain contact may be used. The silicon above the silicon dioxide is removed and additional layers grown, deposited, patterned, etched, diffused, ion implanted, etc. to produce gate insulator/gate oxide 714, gate 716, field oxide 718, source 720, bottom conductive layer, drain contact, drain (in layer 705) etc. that results in a vertical FET in accordance with some embodiments of the invention.

For example, the transistor 700 includes a silicon layer on the GaN epilayer 702 and stress relieving/management layer 705, where the silicon layer can be doped as desired, for example forming a P⁻ body 606 with an N⁻ epi region 712 and N⁺ regions 708, 710 underneath a gate oxide 714 in a SiO2 layer. A gate 716 and field oxide 718 are formed over the gate oxide 714 and underneath a source 720. Again, the transistor 700 is not limited to the example shown in FIG. 7 and may be any suitable type of transistor or other device, such as a MOSFET or field effect transistor of any type and many types of materials including but not limited to metal oxide semiconductor FET (MOSFET), junction FET (JFET), high electron mobility transistor (HEMT), etc., or an insulated gate bipolar transistor (IGBT) or other types of transistor structures including bipolar junction transistors (BJTs), heterojunction bipolar transistors (HBTs), Darlington transistors, etc. and can be made of any suitable material including but not limited to silicon, gallium arsenide, gallium nitride, silicon carbide, etc which has a suitably high voltage rating.

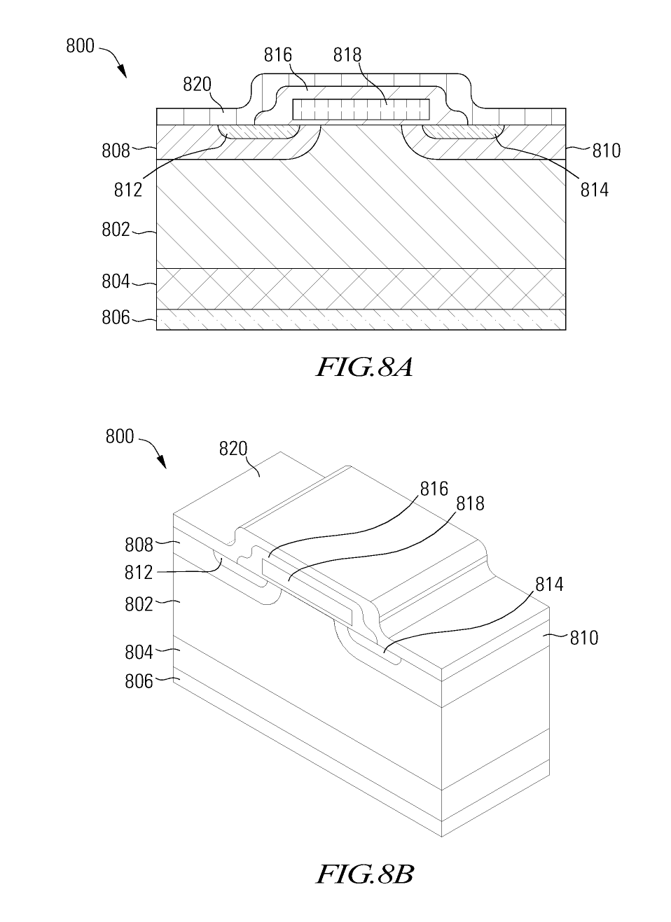

FIGS. 8A-8B depict an embodiment of a transistor 800 (in cross-section and perspective views) with a Si drift region/blocking layer 802 over a N⁺ substrate 804 and stress relieving/management layer/drain terminal 806. P⁺ regions 808, 810 are formed over/in Si drift region/blocking layer 802, with N⁺ regions 812, 814. In some embodiments, the source is formed in a Si layer and is N⁺ Si with a highly conductive Ohmic contact intimately on top of the N+ Si source. Gate 818 is located in an oxide region 816, under source/source ohmic contact 820. Other layers and materials can be included, such as, but not limited to, silicon dioxide, buried oxide(s), other insulators, other conducting layers, other silicon layers that may be doped or undoped, etc. and additional layers grown, deposited, patterned, etched, diffused, ion implanted, etc. to produce gate insulator/gate oxide, gate, field oxide, source, etc. in accordance with some embodiments of the invention. Again, the transistor 800 is not limited to the example shown in FIG. 8 and may be any suitable type of transistor or other device, such as a MOSFET or field effect transistor of any type and many types of materials including but not limited to metal oxide semiconductor FET (MOSFET), junction FET (JFET), high electron mobility transistor (HEMT), etc., or an insulated gate bipolar transistor (IGBT) or other types of transistor structures including bipolar junction transistors (BJTs), heterojunction bipolar transistors (HBTs), Darlington transistors, etc. and can be made of any suitable material including but not limited to silicon, gallium arsenide, gallium nitride, silicon carbide, etc, which has a suitably high voltage rating.

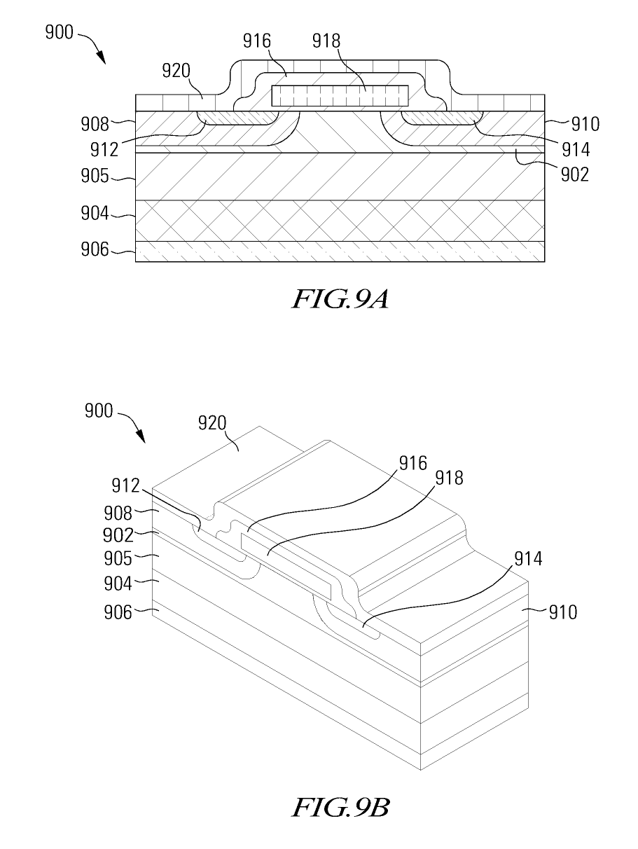

FIGS. 9A-9B depict an embodiment of a transistor 900 (in cross-section and perspective views) with Si drift region/blocking layer 902 and GaN drift region/blocking layer 905 over a N⁺ substrate 904 and stress relieving/management layer/drain terminal 906. P⁺ regions 908, 910 are formed over/in Si drift region/blocking layer 902, with N⁺ regions 912, 914. In some embodiments, the source is formed in a Si layer and is N⁺ Si with a highly conductive Ohmic contact intimately on top of the N+Si source. Gate 918 is located in an oxide region 916, under source/source ohmic contact 920. Other layers and materials can be included, such as, but not limited to, silicon dioxide, buried oxide(s), other insulators, other conducting layers, other silicon layers that may be doped or undoped, etc. and additional layers grown, deposited, patterned, etched, diffused, ion implanted, etc. to produce gate insulator/gate oxide, gate, field oxide, source, etc. in accordance with some embodiments of the invention. Again, the transistor 900 is not limited to the example shown in FIG. 9 and may be any suitable type of transistor or other device, such as a MOSFET or field effect transistor of any type and many types of materials including but not limited to metal oxide semiconductor FET (MOSFET), junction FET (JFET), high electron mobility transistor (HEMT), etc., or an insulated gate bipolar transistor (IGBT) or other types of transistor structures including bipolar junction transistors (BJTs), heterojunction bipolar transistors (HBTs), Darlington transistors, etc. and can be made of any suitable material including but not limited to silicon, gallium arsenide, gallium nitride, silicon carbide, etc which has a suitably high voltage rating.

Standard Si vertical FET processes and processing may be used or the vertical FET process may be modified, changed, optimized, enhanced, improved, altered, etc. as needed or desired to achieve, for example, the desired electrical performance and/or cost structure. Temperature and process profiles, alternations, modification, improvements, enhancements, etc. including those involving, but not limited to, growth, implantation, annealing, rapid thermal annealing, diffusion, oxidation, etching, deposition, crystallization, re-crystallization, crystallographic orientation(s) and structure(s), etc. may be used to realize certain implementations of the present invention.

Although a planar structure is illustrated and depicted in the Figures, the present invention is applicable to any type of vertical transistor and, in particular, field effect transistors, especially vertical field effect transistors including trench vertical FETs, UFETs, VFETs, DFETs, UMOSFETs, VMOSFETs, DMOSFETS, U Groove, V Groove, etc. and may also be applicable to other types of hetero junction and heterostructures including, but not limited to, high electron mobility transistors (HEMTs), modulation doped FETs (MODFETs), other 2-D electron gas transistors, polar transistors, stress-polarization transistors, etc.

Although the Figures depict and illustrate the hetero-interface between the Si and GaN occurring at the junction between the Si p-type body and potentially the Si n-epi to the GaN n-epi, this depiction and illustration is merely for illustrative example purposes and is in no way intended to be limiting. The junction and/or the growth interface between the Si and GaN can for example, but not limited to, occur at any one of a numerous places with a few of these mentioned here: at the p-body interface to the n-epi; at the N⁺ source to p-body interface; within the p-body itself (i.e., a p-Si to p-GaN heterojunction) and any other appropriate interfaces. The thickness of the GaN blocking layer can be tailored and set to meet the specifics of the intended application including the electrical, mechanical, thermal specifications, etc.

Although the Figures depict and illustrate a single GaN epilayer, it is to be understood that the blocking layer could consist of a plurality of layers including a plurality of GaN layer(s), GaN layers with distributed stress management layers and other stress altering, controlling, relief, etc. layers, templates, etc. These plurality of multiple layers can be conductive as needed and also have a high breakdown field and/or other properties depending on the location and purpose of such layers. In addition a transition/buffer layer may exist at the interface between the example GaN epilayer depicted and illustrated in the Figures and the Si material. Such a buffer/transition layer may be thin or thick, may be a nitride material such as AlN or AlGaN or other material including a metal, semiconductor, semi-metal, intermetallic, alloy, compound, element, phase, allotrope(s), other crystalline materials, nanotube(s), a material of any composition and structure, etc or combinations of these in any form and use. A distributed stress-management/control layer or layer(s) may also be used. In addition, with reference to FIGS. 1 through 6 and also the other figures and text herein, vias and/or ‘holes’, etc. can also be etched into and/or created into, for example, the SOI (including the insulator part of the SOI) and SiO₂ layers and films, etc. as needed to support the operation of the embodiments and implementations of the present invention.

Embodiments of the present invention may be grown and fabricated, bonded, assembled, etc. such that the highest temperature processes, growth, operation is below that/compatible with Si power MOSFETs so that no appreciable diffusion including diffusion of junctions occurs and the Si power MOSFET remains intact and unchanged after the completion of the of the incorporation of the GaN drift layer and related layers. In some embodiments of the present invention, the structure can be inverted during growth and fabrication such that the thinned down/etched Si power device effectively acts as a substrate for the growth of the GaN layer(s) which, may be grown on template(s), transition layer(s), buffers, etc.; in some other embodiments of the present invention, the thinned down power MOSFET can be temporarily bonded/attached to a temporary additional substrate that provides, for example, but not limited to, mechanical strength, thermal coefficient of expansion and/or thermal/stress management and relief/reduction/mitigation during, for example, the growth, processing, fabrication and/or assembly, etc. of the present invention. This may be in addition to stress-management and reduction/mitigation layer(s)/film(s) that have been permanently built in/added during the growth and/or subsequent processes and processing, packaging, etc. for example, to maintain proper performance and avoid/mitigate potential mechanical, stress, mismatch, cracking, etc. issues that may otherwise occur during processing, fabrication, assembly, bonding, packaging, operation, etc.

In other embodiments of the present invention, the Si structure may be completely or partially grown/fabricated on a GaN epitaxial material drift region to realize certain embodiments/implementations of the hybrid Si-GaN based vertical power device(s) including, but not limited to, vertical power MOSFETs and IGBTs.

Should the growth of the GaN on Si for the result in temperatures (i.e., the GaN growth/deposition temperature) that may cause diffusion in the dopants and associated junctions (e.g., pn (PN) junctions, nn (NN) junctions, and/or pp (PP) junctions of any doping level) of the Si-based power device(s), then appropriate modifications to the processing and architecture of the Si power device so as to compensate for, for example but not limited to, the diffusion that will occur during the growth of the GaN drift region on the Si power device including potentially one or more of the buffer layer(s), the GaN drift region stress-management layer(s), template(s), adhesion, and/or bonding layer(s)/film(s), etc,

The present invention can allow for thinned downed/etched back power MOSFET structures essentially of any type including those discussed above and then growing a GaN epilayer on, for example, the etched back/thinned down (001) which is also written as (100) orientation Si to create and fabricate a Si power FET structure with, for example, a GaN epitaxial drift region. Such structures can then have an appropriate mechanical and electrical support structure or structures to enable the device to be completed and, for example, packaged. Band gap offsets also referred to band offsets (i.e., conduction band and/or valance band offsets) can be used to support current transport; if necessary additional steps and/or layers including, but not limited to, hetero-interfaces, superlattice(s), heavily doped layers, tunneling layers, tunnel junctions, etc., other processing steps and techniques, or combinations of these, etc. In addition, other methods including but not limited to wafer bonding, other types of bonding, attaching, epitaxial growth, regrowth, diffusion blocking layers, chemical mechanical polishing (CMP), surfactants, templates, crystal orientation, layers, etc. can also be used. The present invention can use but is not limited to using chemical vapor deposition (CVD), metalorganic CVD (MOCVD), organometallic vapor phase epitaxy (OMVPE), atomic layer epitaxy (ALE), atomic layer deposition (ALD), migration-enhanced epitaxy (MEE), elective area growth, selective area epitaxy, molecular beam epitaxy (MBE), gas source molecular beam epitaxy (GSMBE), chemical beam epitaxy (CBE), plasma enhanced CVD (PECVD), plasma enhanced MBE (PEMBE), liquid phase epitaxy (LPE), selective epitaxy growth (SEG), selective area etching (SAE), epitaxial lateral overgrowth (ELO), vapor phase epitaxy (VPE) including all types of VPE, physical vapor deposition (PVD), electron beam evaporation, sputtering, sol gel processes, ink jet, screen printing, chemical etching, dry etching including reactive ion etching (RIE) and deep RIE (DRIE), etc., combinations of these, etc. to create, fabricate, etc., implementations and embodiments of the present invention.

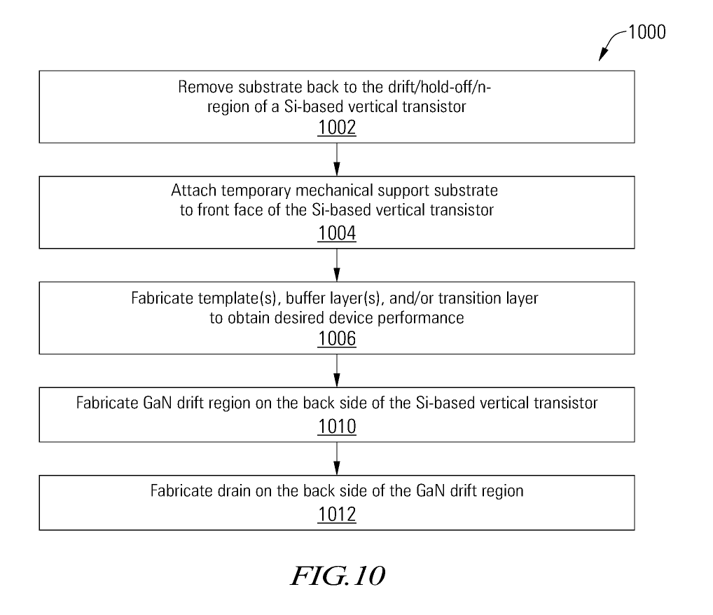

Turning to FIG. 10, flow diagram 1000 depicts an example method for fabricating a vertical enhancement hetero wide bandgap transistor in accordance with some embodiments of the invention. Following flow diagram 1000, a Si-based vertical transistor is fabricated or otherwise obtained or provided. The substrate is removed (e.g. but not limited to, etch, thin, chemical mechanical polish, slice, cut, etc.) back to the drift/hold-off/n⁻ (low doped) region of the Si based vertical transistor structure. (Block 1002) In some embodiments, an appropriate temporary mechanical and/or stress reduction/mitigation/etc. support substrate is optionally attached to the front face (i.e., Source and Gate side) of the Si-based vertical transistor structure resulting from Block 1002. (Block 1004) Grow, deposit, intimately bond/attach/connect/form/etc. the template(s), buffer layer(s), and/or transition layer(s) etc. Use appropriate fabrication and growth conditions in Blocks 1002-1006 to optimize electrical and physical (including diffusion profiles) to obtain desired device performance. (Block 1006) Grow, deposit, intimately bond/attach/connect/form/etc. the GaN drift region to the back side of the Si-based vertical transistor structure resulting from the steps above. (Block 1010) Thickness of GaN drift region can be determined by, for example, the breakdown holdoff voltage and the transistor on resistance. Complete the vertical transistor structure including, for example, adding a drain, a drain ohmic contact and a drain interconnect, etc. Include an appropriate electrical, thermal, stress, mechanical substrate including as part of the drain if needed. Assemble, bond, package, etc. the Si- and GaN-based transistor/switching device, etc. (Block 1012) The term “create” is used herein to refer generically to any method or technique for growing, forming, depositing, fabricating, evaporating, etc. layers and/or structures in the device, and should not be interpreted as being limited to any particular technique. Notably, in some embodiments, SiC and other materials are used in place of the GaN and related materials.

Integration and co-integration of radio frequency (RF), microwave, millimeter-wave (mm-wave), optical, opto-electronics, light emitting diodes (LEDs), solid state lasers, integrated circuits (ICs), application specific integrated circuits (ASICs), memory including but not limited to, FLASH, electrically erasable read only memory (EEPROM, E2PROM, etc.), programmable read only memory (PROM), random access memory (RAM), static random access memory (SRAM), high temperature electronics, etc. The present invention allows the integration of lateral and vertical devices including but not limited to GaN-related containing material (i.e., GaN, AlGaN, AlN, etc.) with Si-based power devices and ICs including but not limited to complementary metal oxide semiconductor (CMOS), SOI, n-channel MOS (NMOS), p-channel MOS (PMOS), doubly diffused MOS (DMOS), bipolar CMOS DMOS (BCD), etc.

The present invention allows for the replacement of the Si drift region/voltage blocking/holding region of a power transistor with a GaN drift region/voltage blocking/holding region and by doing so to, among other things, achieve higher, better, greater, etc. performance.

The examples, illustrations, Figures and implementations contained within are not to be construed as limiting in any way or form.

The example embodiments disclosed herein illustrate certain features of the present invention and are not limiting in any way, form or function of present invention. The present invention is, likewise, not limited in materials choices including semiconductor materials such as, but not limited to, silicon (Si), silicon carbide (SiC), silicon on insulator (SOI), other silicon combination and alloys such as silicon germanium (SiGe), etc., diamond, graphene, gallium nitride (GaN) and GaN-based materials, gallium arsenide (GaAs) and GaAs-based materials, etc.

The present invention can include many types of switching elements including, but not limited to, field effect transistors (FETs) such as metal oxide semiconductor field effect transistors (MOSFETs) including either p-channel or n-channel MOSFETs, junction field effect transistors (JFETs), metal emitter semiconductor field effect transistors (MESFETs), other double diffused MOSFETs and lateral diffused MOSFETs (LDMOS), etc. again, either p-channel or n-channel or both, high electron mobility transistors (HEMTs), unijunction transistors, modulation doped field effect transistors (MODFETs), insulated gate bipolar transistor (IGBT), BCD devices including but not limited to transistors, other types of transistors, switches, structures, including but not limited to silicon controlled rectifiers, diodes, rectifiers, triacs, thyristors, etc. The present invention may also be applicable to certain types of hetero-interface or heterojunction bipolar transistors.

While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. An apparatus comprising:
a vertical transistor fabricated on a silicon-based substrate; and
a non-silicon blocking layer adjacent the silicon-based substrate.

2. The apparatus of claim 1, wherein a breakdown voltage of the vertical transistor is increased by the non-silicon blocking layer.

3. The apparatus of claim 1, wherein an on-resistance of the vertical transistor is decreased by the non-silicon blocking layer.

4. The apparatus of claim 1, wherein the vertical transistor comprises a metal oxide semiconductor field effect transistor.

5. The apparatus of claim 1, wherein the vertical transistor comprises a power metal oxide semiconductor field effect transistor.

6. The apparatus of claim 1, wherein the non-silicon blocking layer comprises a gallium nitride blocking layer.

7. The apparatus of claim 1, wherein the non-silicon blocking layer comprises a silicon carbide blocking layer.

8. The apparatus of claim 1, wherein the non-silicon blocking layer replaces a silicon blocking layer.

9. The apparatus of claim 1, wherein the non-silicon blocking layer is created on a 100 orientation silicon layer.

10. The apparatus of claim 1, wherein the non-silicon blocking layer is created on a 001 orientation silicon layer.

11. The apparatus of claim 1, further comprising a mechanical stress relieving layer fabricated on the non-silicon blocking layer.

12. The apparatus of claim 11, wherein the mechanical stress relieving layer comprises a drain, and wherein the vertical transistor further comprises a gate and a source.

13. The apparatus of claim 1, further comprising a silicon drift region.

14. The apparatus of claim 1, wherein the vertical transistor comprises an enhancement-mode device.

15. The apparatus of claim 1, wherein the vertical transistor comprises a depletion-mode device.

16. The apparatus of claim 1, wherein the vertical transistor comprises an insulated gate bipolar transistor.

17. The apparatus of claim 1, wherein the vertical transistor is integrated with at least one complementary metal oxide semiconductor device.

18. A method of fabricating a vertical enhancement transistor, comprising:
removing at least a portion of a silicon substrate of the vertical enhancement transistor to a drift region;
creating a gallium nitride blocking layer in place of the removed silicon substrate; and
creating a drain on the gallium nitride blocking layer.

19. The method of claim 18, further comprising attaching a support substrate to a front face of the vertical enhancement transistor.

20. The method of claim 18, wherein the drain comprises a stress-relieving layer.
